(19) United States
(12) Patent Application Publication
(10) Pub. No.: US 2025/0046581 A1
(43) Pub. Date: Feb. 6, 2025

(54) EXTERNAL MAGNETIC FIELD-COUPLED PLASMA ATOMIC LAYER DEPOSITION DEVICE AND ATOMIC LAYER DEPOSITION METHOD

(71) Applicant: Research & Business Foundation SUNGKYUNKWAN UNIVERSITY, Suwon-si (KR)

(72) Inventors: Ji Eun KANG, Yongin-si (KR); Seung Yup CHOI, Pyeongtaek-si (KR); Geun Young YEOM, Seoul (KR); You Jin JI, Suwon-si (KR); Sun Jae JEONG, Hwaseong-si (KR)

(73) Assignee: Research & Business Foundation SUNGKYUNKWAN UNIVERSITY, Suwon-si (KR)

(21) Appl. No.: 18/789,306

(22) Filed: Jul. 30, 2024

(30) Foreign Application Priority Data
Aug. 4, 2023 (KR) 10-2023-0102296

(51) Int. Cl. H01J 37/32; C23C 16/50

(52) U.S. Cl. CPC H01J 37/3266; C23C 16/50; H01J 37/32568; H01J 2237/332

(57) ABSTRACT

An external magnetic field-coupled plasma atomic layer deposition device of the disclosure includes: a chamber with a stage inside which a substrate is placed; a plasma generation unit that generates plasma in the chamber by forming an electric field; and a magnetic field forming unit provided outside the chamber, which forms a magnetic field to form a density of plasma inside the chamber at a high density.

### BACKGROUND

The disclosure relates to an external magnetic field-coupled plasma atomic layer deposition device and an atomic layer deposition method, and more specifically, to an external magnetic field-coupled plasma atomic layer deposition device and an atomic layer deposition method capable of forming a high-density plasma and depositing an atomic layer by coupling a very high frequency (VHF) plasma using a floating split electrode with an external magnetic field.

Atomic layer deposition (ALD) is similar to a general chemical vapor deposition method in that it utilizes a chemical reaction between gas molecules. However, unlike a conventional chemical vapor deposition method (CVD) in which a plurality of gas molecules are simultaneously injected into a chamber to deposit a generated reaction product on a substrate, the atomic layer deposition method (ALD) differs in that a product is deposited by chemical reaction between source materials on the substrate surface by injecting gas containing one source material into the chamber, chemically adsorbing it to the heated substrate, and then injecting gas containing another source material into the chamber. The atomic layer deposition (ALD) method is currently widely used because it has the advantage of being able to deposit a pure thin film with excellent step coverage characteristics and low impurity content.

The atomic layer deposition (ALD) method is divided into thermal ALD and plasma-enhanced atomic layer deposition (PEALD) depending on the reaction material used in the process. Thermal atomic layer deposition provides the reactant reacting with the metal precursor material in a gaseous state, while plasma atomic layer deposition provides a reactant in a plasma state. Plasma-enhanced atomic layer deposition (PEALD) method using a highly reactive reactant has the advantages of higher growth rate, denser thin film density, and lower process temperature than thermal atomic layer deposition.

However, conventional capacitively coupled-type plasma atomic layer deposition (PEALD) method has a problem of low deposition rate due to low plasma density and low step coverage. Therefore, an atomic layer deposition device and atomic layer deposition method having high plasma density and high step coverage at low deposition temperature are required.

### RELATED ART

### Patent Literature

[Patent Document 1] Korea Registered Patent Publication No. 1662194 (Title of Invention: Plasma Atomic Layer Deposition Device and Method for Forming Oxide Thin Film Using Plasma Atomic Layer Deposition, Registration Date: Sep. 27, 2016)

### SUMMARY

Therefore, an aspect of the disclosure is to solve such a conventional problem, and to provide an external magnetic field-coupled plasma atomic layer deposition device and an atomic layer deposition method that may effectively decompose a process gas to form a high-density plasma, thereby solving problems such as existing poor step coverage characteristics and low deposition rate.

To achieve the aspect, an external magnetic field-coupled plasma atomic layer deposition device according to an embodiment of the disclosure is characterized by including: a chamber with a stage inside which a substrate is placed; a plasma generation unit that generates plasma in the chamber by forming an electric field; and a magnetic field forming unit, which is provided outside the chamber and forms a magnetic field to create a high-density plasma within the chamber, is characterized by being included.

According to an embodiment of the disclosure, an angle formed between a direction of an electric field formed by the plasma generation unit and a direction of a magnetic field formed by applying power to the magnetic field forming unit may be from 0 to 360 degrees.

According to an embodiment of the disclosure, the plasma generation unit may include a plurality of split electrodes that are adjacent to each other and electrically coupled, and generates an electric field in multiple directions when power is applied.

According to an embodiment of the disclosure, each of the plurality of split electrodes may be arranged in a lattice arrangement or an amorphous arrangement.

According to an embodiment of the disclosure, the plasma generation unit may be installed either outside or inside the chamber.

According to an embodiment of the disclosure, an intensity of a magnetic field formed by the magnetic field forming unit is adjusted to control ion collision energy and plasma density responsive to the substrate.

According to an embodiment of the disclosure, the magnetic field forming unit may include an electromagnet or a permanent magnet.

To achieve the aspect, an external magnetic field-coupled plasma atomic layer deposition method according to an embodiment of the disclosure is characterized by including: a precursor adsorption step of placing a substrate inside a chamber and injecting a precursor; a precursor purge step of removing a precursor remaining inside the chamber without reacting with the substrate among the precursors injected in the precursor adsorption step; a plasma forming step of injecting a reactant gas into the chamber and simultaneously applying power to the plasma generation unit and the magnetic field forming unit to convert the reactant gas into a plasma state; and a plasma purge step of removing the plasma reaction species after the precursor reacts with the plasma reaction species formed in the plasma forming step.

According to an embodiment of the disclosure, in the plasma forming step, an angle formed between a direction of an electric field formed by the plasma generation unit and a direction of a magnetic field formed by applying power to the magnetic field forming unit may be from 0 to 360 degrees.

According to an external magnetic field-coupled plasma atomic layer deposition device and an atomic layer deposition method according to embodiments of the disclosure, the process gas may be more effectively decomposed and thereby plasma may be formed at a high density, which may improve step coverage characteristics and deposition rate during atomic layer deposition.

The effects of the disclosure are not limited to the effects mentioned above, and other effects not mentioned will be clearly understood by those skilled in the art from the description of the claims.

### BRIEF DESCRIPTION OF THE DRAWINGS

FIG. 1 is a diagram showing an overall configuration of an external magnetic field-coupled plasma atomic layer deposition device according to an embodiment of the disclosure.

FIG. 2 is a diagram for explaining that an electron density increases as an intensity of an external magnetic field increases in an external magnetic field-coupled plasma atomic layer deposition device according to an embodiment of the disclosure.

FIG. 3 is a diagram for explaining that the difference between plasma potential Vp and floating potential Vf decreases as an intensity of an external magnetic field increases in an external magnetic field-coupled plasma atomic layer deposition device according to an embodiment of the disclosure.

FIG. 4A is a diagram showing a state in which a deposition process is performed in a high-density plasma in an external magnetic field-coupled plasma atomic layer deposition device according to an embodiment of the disclosure; and FIG. 4B is a diagram showing a state in which a deposition process in a relatively low density plasma in an external magnetic field-coupled plasma atomic layer deposition device according to an embodiment of the disclosure.

FIG. 5 is a flowchart of an external magnetic field-coupled plasma atomic layer deposition method according to an embodiment of the disclosure.

FIG. 6 is a diagram showing a progress cycle of an external magnetic field-coupled plasma atomic layer deposition method according to an embodiment of the disclosure.

FIG. 7A is a diagram showing a comparison of a deposition rate and a refractive index with respect to the amount of precursor used, depending on whether or not an external magnetic field-coupled plasma atomic layer deposition method according to an embodiment of the disclosure is applied; and FIG. 7B is a diagram showing a comparison of a deposition rate and a refractive index with respect to a plasma exposure time, depending on whether or not an external magnetic field-coupled plasma atomic layer deposition method according to an embodiment of the disclosure is applied.

FIG. 8A is a diagram showing the surface roughness when an external magnetic field-coupled plasma atomic layer deposition method according to an embodiment of the disclosure is not applied; and FIG. 8B is a diagram showing the surface roughness when an external magnetic field-coupled plasma atomic layer deposition method according to an embodiment of the disclosure is applied.

FIG. 9A is a diagram showing the wet etch rate according to the presence or absence of application of an external magnetic field-coupled plasma atomic layer deposition method according to an embodiment of the disclosure; FIG. 9B is a diagram showing the thin film density according to the presence or absence of application of an external magnetic field-coupled plasma atomic layer deposition method according to an embodiment of the disclosure.

FIG. 10A is a layered perspective view of a trench structure according to an embodiment of the disclosure; FIG. 10B is a detailed top view of the trench structure removed one Si wafer layer according to an embodiment of the disclosure; and FIG. 10C is a diagram showing the thickness of the deposited silicon nitride film relative to the distance from the side surface of the trench structure, depending on whether or not an external magnetic field-coupled plasma atomic layer deposition method according to an embodiment of the disclosure is applied.

FIG. 11A is a diagram showing the degree of step coverage in a pattern with an aspect ratio of 30:1 when an external magnetic field-coupled plasma atomic layer deposition method according to an embodiment of the disclosure is not applied; and FIG. 11B is a diagram showing the degree of step coverage in a pattern with an aspect ratio of 30:1 when an external magnetic field-coupled plasma atomic layer deposition method according to an embodiment of the disclosure is applied.

### DETAILED DESCRIPTION

Hereinafter, embodiments of the disclosure will be described in detail with reference to the accompanying drawings.

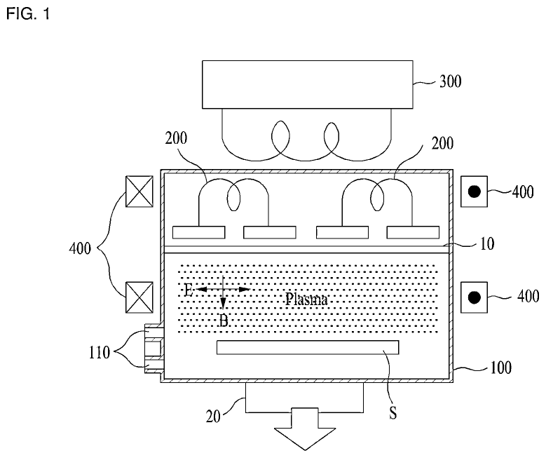

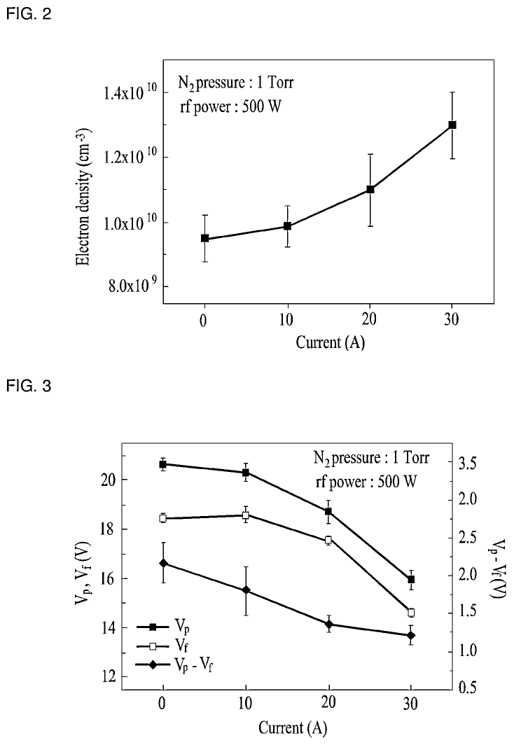

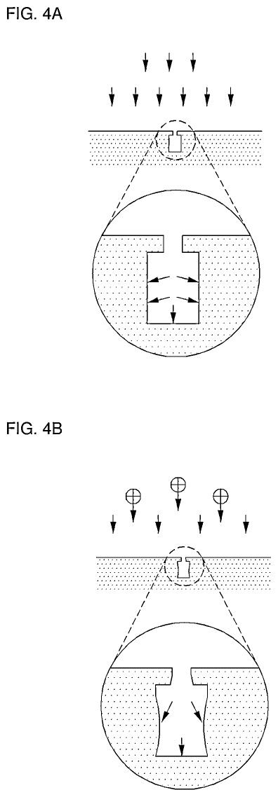

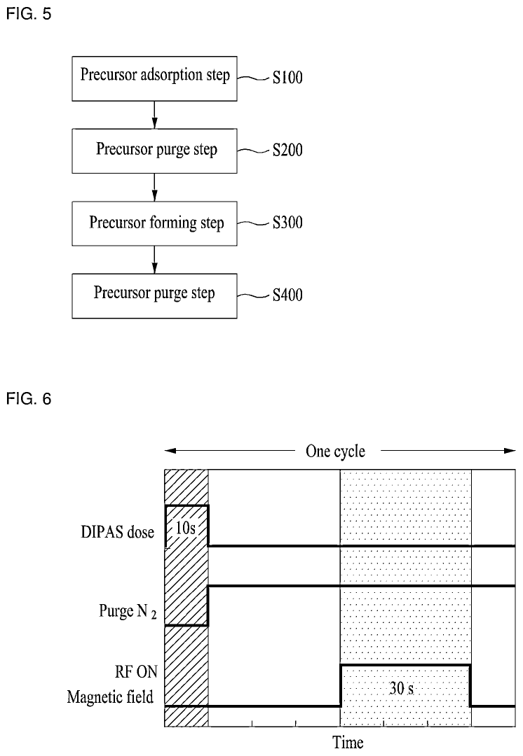

FIG. 1 is a diagram showing an overall configuration of an external magnetic field-coupled plasma atomic layer deposition device according to an embodiment of the disclosure; FIG. 2 is a diagram for explaining that an electron density increases as an intensity of an external magnetic field increases in an external magnetic field-coupled plasma atomic layer deposition device according to an embodiment of the disclosure; FIG. 3 is a diagram for explaining that the difference between plasma potential Vp and floating potential Vf decreases as an intensity of an external magnetic field increases in an external magnetic field-coupled plasma atomic layer deposition device according to an embodiment of the disclosure; FIG. 4A is a diagram showing a state in which a deposition process is performed in a high-density plasma in an external magnetic field-coupled plasma atomic layer deposition device according to an embodiment of the disclosure; FIG. 4B is a diagram showing a state in which a deposition process in a relatively low density plasma in an external magnetic field-coupled plasma atomic layer deposition device according to an embodiment of the disclosure; FIG. 5 is a flowchart of an external magnetic field-coupled plasma atomic layer deposition method according to an embodiment of the disclosure; and FIG. 6 is a diagram showing a progress cycle of an external magnetic field-coupled plasma atomic layer deposition method according to an embodiment of the disclosure.

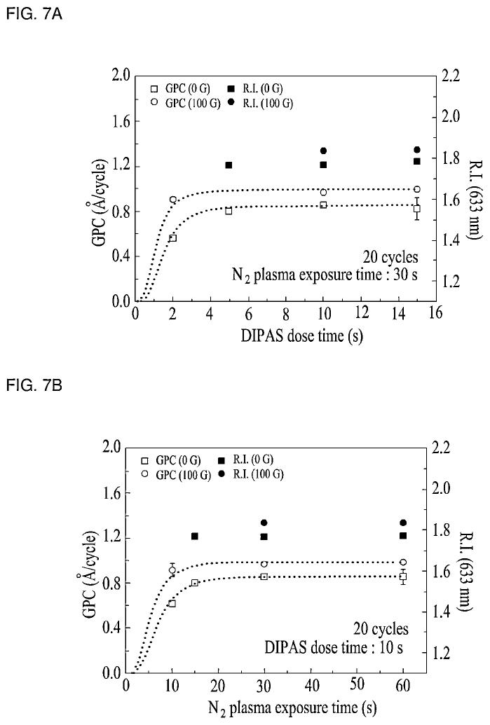

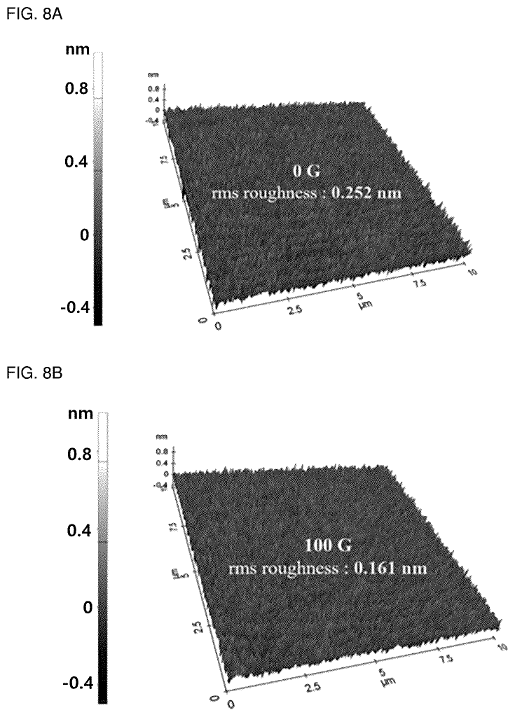

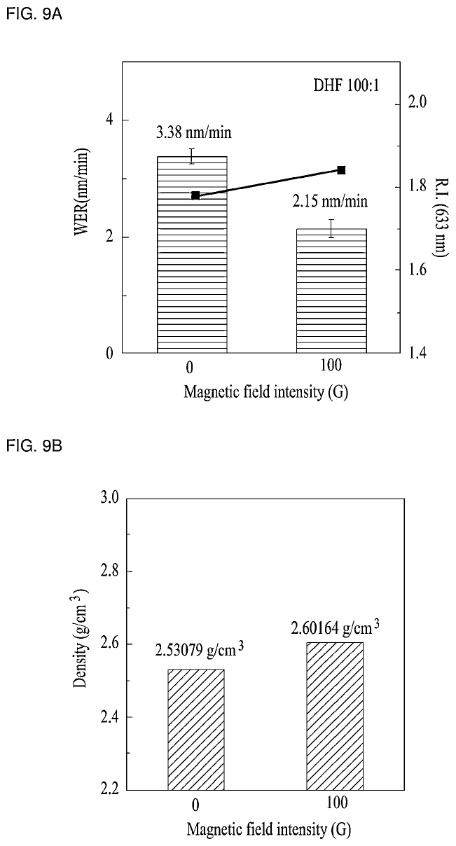

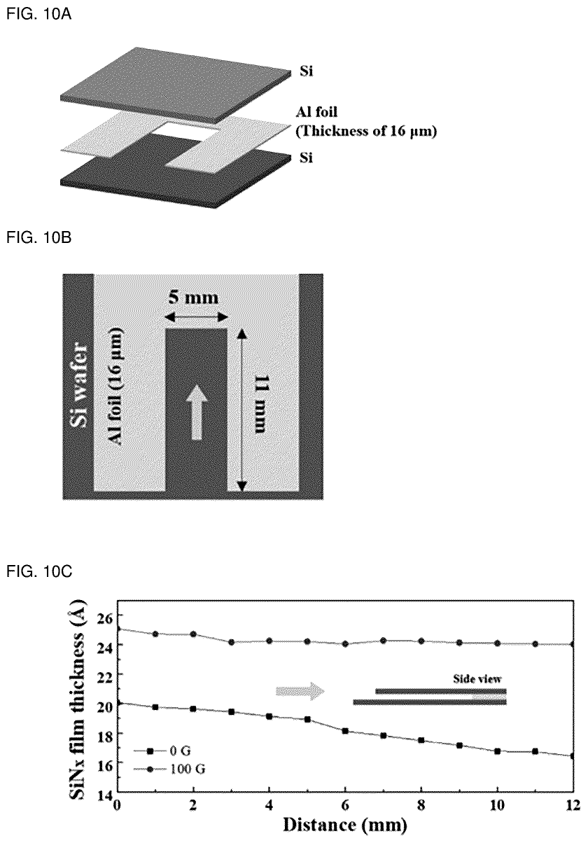

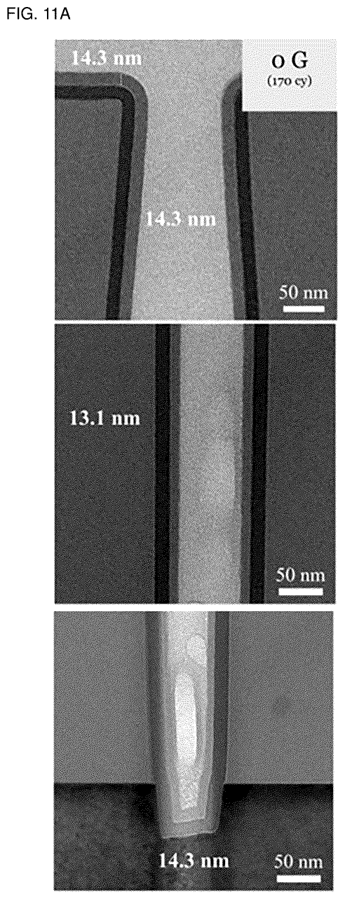

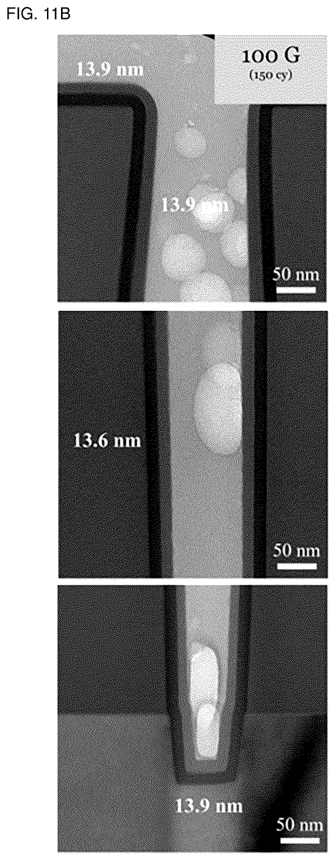

And, FIG. 7A is a diagram showing a comparison of a deposition rate and a refractive index with respect to the amount of precursor used, depending on whether or not an external magnetic field-coupled plasma atomic layer deposition method according to an embodiment of the disclosure is applied; FIG. 7B is a diagram showing a comparison of a deposition rate and a refractive index with respect to a plasma exposure time, depending on whether or not an external magnetic field-coupled plasma atomic layer deposition method according to an embodiment of the disclosure is applied; FIG. 8A is a diagram showing a surface roughness measured using an atomic force microscope (AFM) and represented as a root mean square (RMS) value when an external magnetic field-coupled plasma atomic layer deposition method according to an embodiment of the disclosure is not applied; FIG. 8B is a diagram showing a surface roughness measured using an atomic force microscope (AFM) and represented as a root mean square (RMS) value when an external magnetic field-coupled plasma atomic layer deposition method according to an embodiment of the disclosure is applied; FIG. 9A is a diagram showing the wet etch rate according to the presence or absence of application of an external magnetic field-coupled plasma atomic layer deposition method according to an embodiment of the disclosure; FIG. 9B is a diagram showing the thin film density according to the presence or absence of application of an external magnetic field-coupled plasma atomic layer deposition method according to an embodiment of the disclosure; FIG. 10A is a layered perspective view of a trench structure according to an embodiment of the disclosure; FIG. 10B is a detailed top view of the trench structure removed one Si wafer layer according to an embodiment of the disclosure; FIG. 10C is a diagram showing the thickness of the deposited silicon nitride film relative to the distance from the side surface of the trench structure, depending on whether or not an external magnetic field-coupled plasma atomic layer deposition method according to an embodiment of the disclosure is applied; FIG. 11A is a diagram showing the degree of step coverage after measuring a cross-section of a pattern with an aspect ratio of 30:1 using a transmission electron microscope (TEM) when an external magnetic field-coupled plasma atomic layer deposition method according to an embodiment of the disclosure is applied; and FIG. 11B is a diagram showing the degree of step coverage after measuring a cross-section of a pattern with an aspect ratio of 30:1 using a transmission electron microscope (TEM) when an external magnetic field-coupled plasma atomic layer deposition method according to an embodiment of the disclosure is not applied.

Referring to FIG. 1, an external magnetic field-coupled plasma atomic layer deposition device according to an embodiment of the disclosure includes a chamber 100, plasma generation units 200 and 300, and a magnetic field forming unit 400.

The chamber 100 provides a space in which a plasma atomic layer deposition process is performed. Specifically, a stage (not shown) is provided inside the chamber 100, and a substrate S, which is an object to be deposited, is placed on the stage. Here, the stage may include a substrate S being placed as well as a heating plate capable of heating the substrate S.

Further, the chamber 100 may have a supply portion 110 for supplying a precursor gas, a purge gas, or a reactant gas is supplied, and a pump 20 for exhausting gas inside the chamber 100. In this case, a plurality of supply portions 110 may be provided so that different types of gases are supplied one at a time alternately, rather than simultaneously, when performing the process.

The plasma generation units 200 and 300 generate plasma inside the chamber 100. In this case, the plasma generation units 200 and 300 may include the first plasma generation unit 200 disposed outside the chamber 100 and a second plasma generation unit 300 disposed inside the chamber 100.

The first plasma generation unit 200 may generate very high frequency (VHF) plasma inside the chamber 100 using a very high frequency power source. In this case, a frequency between 60 MHz and 200 MHz may be used for generating the very high frequency plasma.

This first plasma generation unit 200 may include a power generator, a matching network for matching the impedance of the plasma load to the power generator, a power splitter, and the like.

The second plasma generation unit 300 may include floating split electrodes, and specifically, a plurality of split electrodes that are adjacent to each other and electrically coupled, which may include pairs of split electrodes that generate electric fields in multiple directions when power is applied.

In other words, when power is applied to the split electrode pairs, electric fields forming various angles with the substrate S are generated between the plurality of split electrodes.

Here, each of the plurality of split electrodes may be arranged in a lattice arrangement (Checkerboard arrangement) or an amorphous arrangement. That is, each of the plurality of split electrodes may be installed in various arrangements as appropriate for generating plasma.

Meanwhile, the second plasma generation portion 300 is disposed on the upper surface of the quartz plate 20 provided inside the chamber 100 and features a divided electrode structure, thereby reducing non-uniform plasma characteristics appearing in the existing VHF plasma, and enabling effective uniform plasma formation.

The magnetic field forming unit 400 is provided both inside and outside the chamber 100, and generates the magnetic field B to form the density of the plasma inside the chamber 100 at a high density. Specifically, the magnetic field forming unit 400 may include an electromagnet or a permanent magnet.

When the magnetic field forming unit 400 includes an electromagnet, the magnetic field forming unit 400 may include a coil wound around the outside the chamber 100, and the coil may be used to generate a magnetic field.

In this case, an angle formed between a direction of an electric field formed by the plasma generation units 200 and 300 and a direction of a magnetic field formed by applying power to the magnetic field forming unit 400 may be from 0 to 360 degrees.

That is, a direction of the magnetic field may be formed at various angles with respect to any one of the directions of the electric field formed at various angle with respect to the substrate S.

Subsequently, in the magnetic field forming unit 400, an intensity of a magnetic field formed by the magnetic field forming unit 400 is adjusted to control ion collision energy responsive to the substrate S.

Referring to FIG. 2, it may be seen that the electron density increases as an intensity of an external magnetic field increases. In addition, referring to FIG. 3, it may be confirmed that the difference value between a plasma potential Vₚ and a floating potential V_{f} decreases as an intensity of an external magnetic field increases. It may be seen that applying an external magnetic field has an effect of increased plasma density and decreased ion collision energy, thereby adjusting the intensity of a magnetic field to control the ion collision energy.

Meanwhile, the intensity of a magnetic field in a magnetic field forming unit 400 may be adjusted by the number of windings of a coil wound around the outside the chamber 100, the distance between a chamber and a coil, the intensity of a power supply applied to a coil, and the like.

In addition, using such high-density plasma and low ion energy characteristics may be effective in improving the application range of depositing an atomic layer on the substrate S.

Referring to FIG. 4A, when the deposition process is performed in high-density plasma, a sufficient amount of reaction species may be supplied to the deep inside of the trench pattern, and plasma damage on the upper surface of the trench pattern may be reduced.

On the other hand, referring to FIG. 4B, when the deposition process is performed in a relatively low-density plasma, a sufficient amount of reaction species may not be supplied to the deep inside of the trench pattern.

That is, by coupling the external magnetic field to the very high frequency plasma, the magnetic field forming unit 400 may more effectively decompose the process gas by forming the particle density of the plasma at a high density, and may be effective in improving the application range of depositing an atomic layer on the substrate S.

The plasma atomic layer deposition device according to the disclosure has been described above, and the plasma atomic layer deposition method according to the disclosure will be described below.

FIG. 5 is a flowchart of a plasma atomic layer deposition method according to an embodiment of the disclosure, and FIG. 6 is a diagram showing a progress cycle of a plasma atomic layer deposition method according to an embodiment of the disclosure.

Referring to FIGS. 5 and 6, an external magnetic field-coupled plasma atomic layer deposition method according to an embodiment of the disclosure includes a precursor adsorption step S100, a precursor purge step S200, a plasma formation step S300, and a plasma purge step S400.

The precursor adsorption step S100 is a step of placing a substrate S inside a chamber 100 and injecting a precursor, and is a first step for depositing an atomic layer on a substrate S.

The precursor purge step S200 is a step of removing a precursor remaining inside the chamber 100 without reacting to the substrate.

The plasma formation step S300 is a step of injecting a reactant gas into the chamber 100 and simultaneously applying power to the plasma generation units 200 and 300 and the magnetic field forming unit 400 to convert the reactant gas into a plasma state.

Specifically, this step is a step of generating very high frequency plasma inside the chamber 100 using a very high frequency (VHF) power source in plasma generation units 200 and 300, in which power may be applied to the split electrode pairs to generate an electric field in a horizontal direction with respect to the substrate S inside the chamber 100 between the first split electrode and the second split electrode that are adjacent to each other and electrically coupled.

In addition, power may be applied to a magnetic field forming unit 400 to improve the density of the plasma formed inside the chamber 100. Specifically, a magnetic field forming unit 400 may include a coil wound around the outside a chamber 100, and the coil may be used to generate a magnetic field outside the chamber 100.

In other words, during the plasma forming step S300, plasma may be formed by generating an internal electric field and an external magnetic field simultaneously with the injection of a reaction gas into the chamber 100. This enables the plasma reaction species and the precursor to react.

Meanwhile, in the plasma forming step S300, a direction of an electric field and a direction of an magnetic field formed by applying power to the plasma generation units 200 and 300 and the magnetic field forming unit 400 may be perpendicular to each other.

The plasma purge step S400 is a step of removing the plasma reaction species after the precursor reacts with the plasma reaction species formed in the plasma forming step S300.

The plasma atomic layer deposition method according to the disclosure has been described above, and the results derived according to the degree of external magnetic field coupling in the plasma atomic layer deposition method of the disclosure will be described below. Magnetic field intensity is 0 G when no current is applied to the magnetic field forming unit, and magnetic field intensity is 100 G when a current of 30 A is applied to the magnetic field forming unit.

FIG. 7A shows a state of saturation with the amount of DIPAS used, which is a precursor, and FIG. 7B show a state of saturation with the time of exposure to the N₂ plasma. Referring to these, it appears that the deposition rate is higher when an external magnetic field is applied than when the external magnetic field is not applied.

Referring to FIG. 8A, when current is not applied to an external magnetic field forming unit, the root mean square value of the surface roughness is 0.252 nm, whereas, referring to FIG. 8B, when current is applied to the external magnetic field forming unit, the root mean square value of the surface roughness is 0.161 nm.

Referring to FIGS. 9A and 9B, when an external magnetic field is applied, a lower wet etch rate and a higher thin film density are shown than when the external magnetic field is not applied.

Referring to FIG. 10C, in the Trench structure of FIG. 10A and FIG. 10B, when an external magnetic field is applied, the thickness of the silicon nitride film that is deposited by penetrating to the side surface appears more uniform than when the external magnetic field is not applied.

Referring to FIG. 11A, when current is not applied to an external magnetic field forming unit, the step coverage of the side surface and the bottom surface is 91% and 99%, respectively, whereas, referring to FIG. 11B, when current is applied to the external magnetic field forming unit, the step coverage of the side surface and bottom surface is 98% and 100%, respectively.

That is, when an external magnetic field is coupled to the plasma atomic layer deposition method, a high deposition rate may be achieved due to high-density plasma and low ion energy than when the external magnetic field is not coupled, so it may be effective in obtaining a high-quality film with a dense surface and high step coverage.

The scope of the disclosure is not limited to the above-described embodiments and modifications, but may be implemented in various forms of embodiments within the scope of the appended claims. Any person skilled in the art to which the disclosure belongs, without departing from the gist of the disclosure claimed in the claims, shall be deemed to be within the scope of the claims of the disclosure to various modifications.

### DESCRIPTION OF SIGNS

100: chamber
200, 300: plasma generation unit
400: magnetic field forming unit

What is claimed is:

1. An external magnetic field-coupled plasma atomic layer deposition device, comprising:
a chamber with a stage inside which a substrate is placed;
a plasma generation unit that generates plasma in the chamber by forming an electric field; and
a magnetic field forming unit, which is provided outside the chamber and forms a magnetic field to create a high-density plasma within the chamber, is characterized by being included.

2. The external magnetic field-coupled plasma atomic layer deposition device of claim 1, wherein:
an angle formed between a direction of an electric field formed by the plasma generation unit and a direction of a magnetic field formed by applying power to the magnetic field forming unit is from 0 to 360 degrees.

3. The external magnetic field-coupled plasma atomic layer deposition device of claim 1, wherein:
the plasma generation unit comprises a plurality of split electrodes that are adjacent to each other and electrically coupled, and generates an electric field in multiple directions when power is applied.

4. The external magnetic field-coupled plasma atomic layer deposition device of claim 3, wherein:
each of the plurality of split electrodes is arranged in a lattice arrangement or an amorphous arrangement.

5. The external magnetic field-coupled plasma atomic layer deposition device of claim 1, wherein:
the plasma generation unit is installed either outside or inside the chamber.

6. The external magnetic field-coupled plasma atomic layer deposition device of claim 1, wherein:
an intensity of a magnetic field formed by the magnetic field forming unit is adjusted to control ion collision energy and plasma density responsive to the substrate.

7. The external magnetic field-coupled plasma atomic layer deposition device of claim 1, wherein:
the magnetic field forming unit comprises an electromagnet or a permanent magnet.

8. An external magnetic field-coupled plasma atomic layer deposition method using the external magnetic field-coupled plasma atomic layer deposition device according to claim 1, comprising:
a precursor adsorption step of placing a substrate inside a chamber and injecting a precursor;
a precursor purge step of removing a precursor remaining inside the chamber without reacting with the substrate among the precursors injected in the precursor adsorption step;
a plasma forming step of injecting a reactant gas into the chamber and simultaneously applying power to the plasma generation unit and the magnetic field forming unit to convert the reactant gas into a plasma state; and
a plasma purge step of removing the plasma reaction species after the precursor reacts with the plasma reaction species formed in the plasma forming step.

9. The external magnetic field-coupled plasma atomic layer deposition method of claim 8, wherein:
in the plasma forming step, an angle formed between a direction of an electric field formed by the plasma generation unit and a direction of a magnetic field formed by applying power to the magnetic field forming unit is from 0 to 360 degrees.
